(19) United States
(12) Patent Application Publication
(10) Pub. No.: US 2016/0291108 A1
(43) Pub. Date: Oct. 6, 2016

(54) METHOD AND DEVICE FOR FREQUENCY ADJUSTMENT OF A MAGNETIC RESONANCE IMAGING APPARATUS USING AN INVERSION PULSE

(71) Applicant: Siemens Aktiengesellschaft, Muenchen (DE)

(72) Inventors: Daniel Niederloehner, Erlangen (DE); Guenter Schnur, Hemhofen (DE)

(73) Assignee: Siemens Aktiengesellschaft, Muenchen (DE)

(21) Appl. No.: 15/088,710

(22) Filed: Apr. 1, 2016

(30) Foreign Application Priority Data
Apr. 2, 2015 (DE) 102015206053.5

(51) Int. Cl. G01R 33/48; G01R 33/561; G01R 33/483

(52) U.S. Cl. CPC G01R 33/4828; G01R 33/483; G01R 33/5617

(57) ABSTRACT

In a magnetic resonance (MR) system and method for determining an MR system frequency for a region to be examined that has multiple materials therein, a first frequency spectrum is acquired by the execution of a first RF excitation sequence. A second frequency spectrum for the region is acquired by radiation of an RF inversion pulse and execution of a second RF excitation sequence, at the point in time at which the relaxation curve of one of the materials has a zero-crossing. Subsequently, echo signals excited by the second RF excitation sequence are read out, from which a frequency spectrum is determined. The first frequency spectrum and the second frequency spectrum are compared. On the basis of the comparison, maxima of the first frequency spectrum are allocated to different materials. The system frequency is determined on the basis of the allocation of the maxima.

### BACKGROUND OF THE INVENTION

1. Field of the Invention

The invention concerns a method for determining a system frequency for a magnetic resonance (MR) apparatus. The invention further concerns a system frequency determining device, as well as a magnetic resonance system embodying such a device.

2. Description of the Prior Art

In the generation of magnetic resonance scans, the body to be examined is subjected to a relatively large basic magnetic field of, for example, 1.5 Tesla, 3 Tesla or in relatively new high magnetic field systems, even of 7 Tesla. Then, using a suitable antenna system, a radio-frequency excitation signal is emitted which serves to tilt the nuclear spin of particular atoms, stimulated into resonance by this radio-frequency field, through a particular flip angle relative to the magnetic field lines of the basic magnetic field. The radio-frequency signal radiated by the nuclear spins during the relaxation thereof, the magnetic resonance signal, is then received with suitable antennas that can be the same as the transmitting antenna device. The raw data thus acquired are used to reconstruct the desired image data. For spatial encoding of the magnetic resonance signals, defined magnetic field gradients are superimposed on the basic magnetic field during transmission and reception of the radio-frequency magnetic fields.

Before the actual image recording in the context of an examination of a patient by the operation of such a magnetic resonance scanner, a frequency adjustment must be carried out. The goal of the frequency adjustment, before an MR image recording, is a reliable and precise determination of the system frequency, which is also referred to as the “water frequency”. The water frequency corresponds to the frequency of protons bound water molecules. This determination is necessary because the basic magnetic field can be altered by the object to be examined that has been introduced and depends on the measurement volume in the MR system.

In order to ensure a reliable frequency adjustment, maxima of a spectral distribution of MR signals acquired must be analyzed, correctly determined, and finally associated with the right substance, for example, fat, water or silicone.

The measurement to determine the system frequency is carried out with the use of a so-called STEAM sequence (STEAM=stimulated echo acquisition method). In the STEAM sequence, a stimulated echo is generated, wherein for each of the three dimensions, an RF pulse is generated as an excitation pulse and temporally matched thereto, in each case, a selection gradient is switched in order to restrict the measuring range in the respective dimension to a region under examination VOI. With the use of the excitation signal, a magnetization is generated in the region under examination, the magnetization being linked to the echo signal which is read with the use of an antenna system. The excitation signal has a particular frequency bandwidth so that protons in different materials and configurations and positions are excited with different frequencies and also contribute to the echo signal with different frequencies. This echo signal is a type of global response of the material present in the region under examination VOI to the excitation signal described. The raw data generated on the basis of the echo signals are converted into spectral data by a Fourier transform. The system frequency to be read from the spectral data can be understood as a type of average water frequency. For example, when evaluating the spectral data, a maximum is sought which corresponds to the frequency of the echo signals of the protons of the water molecules.

Since, however, the basic magnetic field B₀ as well as the exciting magnetic field have an inhomogeneity, the echo signals from the water molecules are nevertheless also spatially-dependent so that the maximum that is associated with the water frequency can be unsharp or can degenerate, i.e. can be split into a number of maxima. Furthermore, it is also possible that maxima of different materials overlap in the previously acquired frequency spectrum. A clear and precise determination of the system frequency based on the previously scanned frequency spectrum is therefore often associated with difficulties.

A conventional method for determining the system frequency for the frequency adjustment is based on the determination of a cross-correlation between the previously acquired frequency spectrum and a model with two maxima (water and fat at −3.4 ppm of water). This procedure functions well if exactly two maxima are presented in the acquired spectrum. The primary contributions to the frequency spectrum are then made by the frequencies of the protons bound into the water and into the fat.

For correct allocation of the maxima found, alternatively or additionally, for example, in the event that fat dominates, a switch can be actuated on the MR system before the recording of the frequency spectrum, the actuation of which is based on the assumption that fat dominates in the MR image. In this case, the primary maximum is associated with the substance fat.

In addition, in breast examinations, the substance silicone can be present, which brings with it a third frequency component (at −4.5 ppm of water) in the measured frequency spectrum. In this case, also, conventionally a special mode can be activated in which silicone is taken into account in a model with two maxima in which fat is replaced by silicone. In the case of an unclear detection of a single maximum, in this variant it is determined that the main maximum is associated with the substance silicone.

In addition, it is often not known which materials are contained in a region under examination, so that a correct allocation of the maxima is further hindered.

Conventionally, therefore, it must first be established whether silicone is present or not. Therefore, an interaction of the user is required, who has to decide, based on image data whether silicone is present in the region under examination or not. However, this requires additional operational steps which also require a certain degree of experience from the operating personnel. However, an automatic detection of silicone is not possible in this conventional method.

If the external circumstances are difficult when, for example, the basic magnetic field B₀ is not very homogeneous, then a correct allocation of the maxima is barely possible and the maxima are allocated in part incorrectly. An incorrect allocation of this type can result, such as during the following image recording of a region under examination VOI of a patient, in a fat saturation not taking place satisfactorily or even in the water signal being saturated. A false saturation of this type can lead to falsified image recordings, which can result in false diagnoses.

### SUMMARY OF THE INVENTION

An object of the present invention is to provide a more effective and more reliable method for determining a system frequency in the MR imaging which is, in particular, less time-intensive.

In the method according to the invention for determining an MR system frequency for a region under examination that has multiple materials therein, a first frequency spectrum is acquired with the use of a first RF excitation sequence, preferably a first stimulated echo sequence for the region under examination. This procedure corresponds to the measurement of the frequency spectrum for determining the system frequency, as described in the introduction above, before the actual image scan.

An RF excitation sequence as used herein means a pulse sequence with at least one RF excitation pulse. However, the RF excitation sequence can also have multiple RF excitation pulses radiated temporally one after another. The RF excitation sequence can also include gradients activated synchronously with the RF excitation pulses in order to limit the effect of the RF excitation pulses to a pre-determined spatial range in which the measurement is to occur. The RF excitation sequence can be a stimulated echo sequence.

In contrast to the conventional procedure, however, according to the invention, a second frequency spectrum is measured for the region under examination. During this measurement, initially an RF inversion pulse is radiated. This inversion pulse serves to invert the magnetization in the region under examination. Corresponding gradient pulses with which the effect of the inversion pulse on the region under examination is restricted can also be activated simultaneously with the inversion pulse. The inverted magnetization subsequently reverts within a relaxation time to its starting state before the inversion. However, the relaxation time is material-dependent so that the magnetic moments of the individual materials relax at different rates.

Subsequently, a second RF excitation sequence is activated at the point in time at which the relaxation curve of the magnetization, preferably the magnetization in the z-direction, of one of the materials has a zero-crossing. Preferably, a stimulated echo sequence (STEAM sequence) is used as the second excitation sequence. The effect of the RF excitation pulse in such a stimulated echo sequence is restricted, by simultaneously activated gradients, to the region under examination. Since, however, the magnetization in the z-direction of one of the materials at the excitation point in time has the value 0, only the other materials that do not have a magnetization with the value 0 at the excitation point in time are excited. Furthermore, at the echo point in time, an echo signal is acquired and read out.

On the basis of the acquired echo signals, the second frequency spectrum is subsequently determined. Thereafter, the first frequency spectrum and the second frequency spectrum are compared. This means that differences between the two frequency spectra, particularly at the positions of the maxima of the first frequency spectrum are sought. Furthermore, maxima of the first frequency spectrum are associated with different materials on the basis of the comparison. Finally, the system frequency is determined on the basis of the allocation of the maxima. For the determination of the system frequency, a method can be used wherein an analysis of the first frequency spectrum is carried out using a model function with the additional use of the information on the identity of the individual maxima. As mentioned, a cross-correlation between the previously acquired first frequency spectrum and the model function can be carried out and the model function can be adapted so that it correlates optimally with the acquired first frequency spectrum. In order for the adaptation of the model to be carried out correctly, it is of decisive importance to be able to associate the maxima of the acquired first frequency spectrum correctly.

Alternatively, it is also conceivable if, for example, three different materials contribute to the echo signal in the region under examination, but only one model function is available for two materials, or the computation capacities or the examination time available is/are not sufficient for the adaptation of a relatively complex model, so as to carry out the adaptation of this model function by correlation with the second acquired frequency spectrum, since the influence of one of the materials is suppressed.

The control sequence according to the invention for controlling a magnetic resonance imaging system for determining a system frequency for a region under examination in which multiple materials are present, has an inversion pulse and also preferably has multiple gradient pulses that are set to be temporally synchronous with the RF inversion pulse. Furthermore, the control sequence according to the invention has an RF excitation sequence, preferably a stimulated echo sequence, which is placed at a temporal separation or at a point in time after the RF inversion pulse at which the relaxation curve of the magnetization of one of the materials has a zero-crossing. The stimulated echo sequence comprises, for example, a number of RF excitation pulses and a number of gradient pulses that are set temporally synchronous with the excitation pulse. Finally, the control sequence according to the invention has a read-out window that is set to the echo point in time of the excitation pulse.

The system frequency determining device according to the invention has a control sequence generating processor that generates a first RF excitation sequence, preferably a stimulated echo sequence and for generating the control sequence according to the invention for a region under examination. The device has an input interface that receives a first frequency spectrum after generation of the first RF excitation sequence and for acquiring a receiving frequency spectrum after the generation of the control sequence according to the invention. Furthermore, the system frequency determining device according to the invention has a comparator that compares the first frequency spectrum and the second frequency spectrum and an allocation processor that allocates maxima of the first frequency spectrum to different materials or material types on the basis of the comparison. Finally, the system frequency determining device according to the invention has a system frequency determining processor that determines the system frequency on the basis of the allocation of the maxima.

The magnetic resonance imaging system according to the invention has a control computer configured to control scanner of the magnetic resonance imaging system by implementing the method according to the invention. For this purpose, the magnetic resonance imaging system according to the invention embodies the system frequency determining device according to the invention.

The basic components of the system frequency determining device according to the invention can be configured primarily in the form of software components. This particularly relates to the comparator, the allocation processor and the system frequency determining processor. These components also can be realized in part, especially if particularly fast calculations are to be performed, in the form of software-supported hardware, for example, FPGAs or the like. Similarly if, for example, only a transfer of data from other software components is needed, the required interfaces can also be configured as software interfaces. However, they can also be configured as interfaces constructed with hardware, which are controlled by suitable software.

the system frequency determining device can be part of a user terminal or a control computer of a magnetic resonance imaging system.

A realization largely through software has the advantage that, for example, conventionally used control computer can be upgraded easily with a software update in order to operate in the manner according to the invention. In this respect, the above object is also achieved by a non-transitory, computer-readable data storage medium encoded with programming instructions (code). The storage medium can be loaded directly into a memory of a control computer of a magnetic resonance imaging system. The program code causes all the steps of the method according to the invention to be implemented when the program code is executed in the control computer. The storage medium may have additional constituent parts such as documentation and/or additional components including hardware components such as hardware keys (dongles etc.) for the use of the software.

The computer-readable medium may be, for example, a memory stick, a hard disk or another transportable or firmly installed data carrier on which the program code can be read in and executed by the control computer, and serves for transport to the control computer and/or for storage on or in the control computer. For this purpose, the computer unit can have one or more cooperating microprocessors or the like. The computer can be, for example, part of a terminal or the control computer of the magnetic resonance imaging system.

The various features of different exemplary embodiments of the invention can be combined to form further exemplary embodiments.

In an embodiment of the method according to the invention, at least one third frequency spectrum is also included. For the acquisition of the third frequency spectrum, the point in time of emitting an excitation pulse is selected so that the relaxation curve of the magnetization of a different material than for the acquisition of the second frequency spectrum has a zero-crossing. Subsequently, the third frequency spectrum is taken into account in the comparison step, i.e. the maximum that is possibly lacking in the third frequency spectrum serves to identify the corresponding maximum in the first frequency spectrum or the second frequency spectrum.

Preferably, during the allocation step, the allocation of a maximum of the first frequency spectrum to a particular material takes place, depending thereon in which frequency spectrum the maximum is suppressed. Differently expressed, it is known for each of the additional frequency spectra by which material the magnetic resonance signals are suppressed, so that on a comparison of the first frequency spectrum in which all the maxima are present with the additional frequency spectra, an allocation of the individual maxima of the first frequency spectrum to the respective materials allocated to the additional frequency spectra is readily possible.

With the method according to the invention, an allocation of a maximum of the first frequency spectrum to a particular material on the basis of one of the further frequency spectra takes place depending upon the point in time at which an excitation pulse was radiated during the acquisition of the respective further frequency spectrum. As previously stated, with the use of the stipulation of the point in time of the excitation pulse, a material is determined of which the magnetic resonance signals are suppressed during the acquisition of the respective frequency spectrum. Thus, a material can be associated with each of the additional frequency spectra, the resonance frequency of which or the allocated maximum of which does not occur in the respective frequency spectrum. Therefore, by the comparison of the first frequency spectrum, in which all the maxima are present, with the additional frequency spectra, an allocation of the individual maxima of the first frequency spectrum to the materials associated with the respective additional frequency spectra is readily possible.

For suppression of the magnetic resonance signal of one of the materials, the point in time of the radiation of an excitation pulse during the acquisition of the second frequency spectrum is effectively selected by seeking the relaxation curve of the magnetization, or more precisely, the magnetization in the z-direction, of the material that has a zero-crossing at the point in time of the excitation. The z-direction herein means the direction of the system axis of the magnetic resonance tomography scanner (see FIG. 6). As used herein, magnetization means magnetization in the z-direction. During the comparison step, it is then checked, for example, whether and how the acquired second frequency spectrum differs from the first frequency spectrum.

In a further embodiment of the method according to the invention, if it has been determined that the second frequency spectrum does not differ from the first frequency spectrum, it is established that the material being sought is not present in the region under examination. Conversely, if it is determined that the second frequency spectrum differs from the first frequency spectrum, particularly, in a region of the maxima of the first frequency spectrum, it is established that the material being sought is present in the region under examination.

In another embodiment of the method according to the invention, the zero-crossing of the relaxation curve of the magnetization of one of the materials water, fat and silicone is used as the excitation point in time. Thus, the method is particularly suitable for correctly allocating the maxima of the aforementioned materials water, fat and silicone occurring during the acquisition of the frequency spectrum of a region to be investigated, and thus also for correctly using methods based on models for determining the system frequency.

In the step for determining the system frequency, for example, an adaptation of a model function to one of the acquired frequency spectra can be carried out. Typically, a model function comprises a number of parameters which are adapted to the acquired frequency spectrum.

In a further embodiment of the method according to the invention, the system frequency is determined with the use of an adaptation of a model function to the first frequency spectrum. The first frequency spectrum is particularly suitable for adaptation of the model function if the number of maxima in the first frequency spectrum corresponds to the number of maxima of the model function to be adapted.

In a version of this embodiment of the method according to the invention, the adaptation of the model function to one of the acquired frequency spectra takes place using a cross-correlation to the acquired frequency spectrum and the model function.

### BRIEF DESCRIPTION OF THE DRAWINGS

FIG. 1 is a graphical representation of a region to be investigated with three maxima.

FIG. 2 is a graphical representation of a pulse sequence with an inversion pulse which is used in a method according to an exemplary embodiment of the invention.

FIG. 3 is a flowchart of the method for determining a system frequency according to a first exemplary embodiment of the invention.

FIG. 4 is a flowchart in detail of step 3.II in the flowchart of FIG. 3.

FIG. 5 is a flowchart of the method for determining a system frequency according to a second exemplary embodiment of the invention.

FIG. 6 schematically illustrates a magnetic resonance imaging system according to an exemplary embodiment of the invention.

### DESCRIPTION OF THE PREFERRED EMBODIMENTS

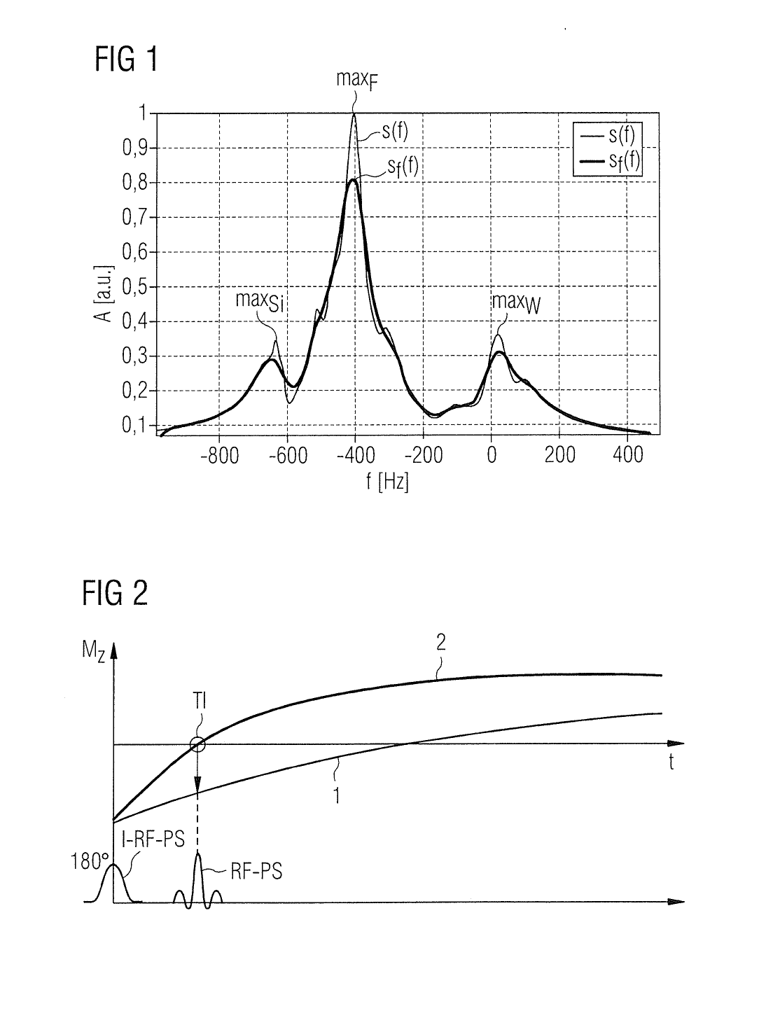

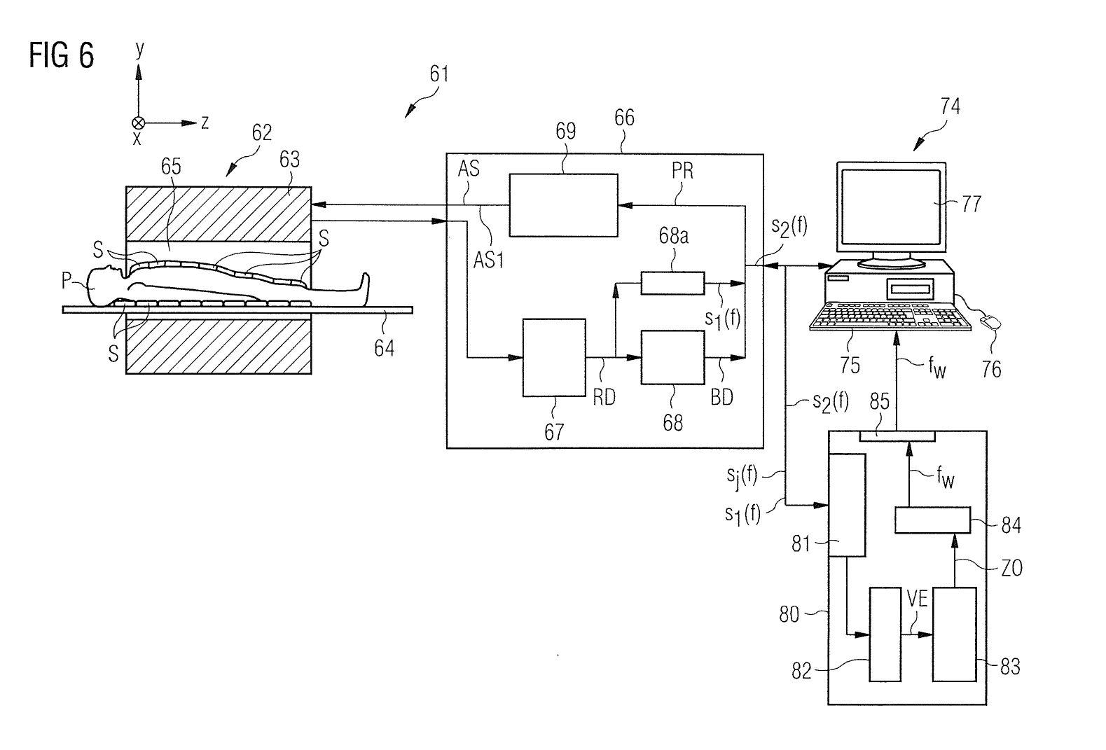

FIG. 1 shows a frequency spectrum s(f) with three maxima. The amplitude A of the frequency spectrum s(f) is plotted in arbitrary units a.u. against the frequency f or the deviation of the frequency from the system frequency f_{w}. In order to acquire the frequency spectrum, in a magnetic resonance system (see FIG. 6), a so-called STEAM sequence is generated and herein stimulated magnetic resonance signals, also called echo signals, are read out. The frequency spectrum s(f) is typically obtained by summing individual spectral curves which are each determined on the basis of signals from individual channels of the antenna system of the magnetic resonance system. Typically, on the basis of the acquired overall frequency spectrum s(f), a filtered frequency spectrum s_{f}(f) is generated wherein a typical filter width of the filter with which the filtered frequency spectrum s_{f}(f) was generated is, for example, 1 ppm. The filtered frequency spectrum s_{f}(f) is taken as the basis for the further evaluation of the frequency spectrum, wherein for location of the system frequency f_{w}, for example, a cross-correlation between a model function and the filtered frequency spectrum s_{f}(f) is carried out.

In the case shown in FIG. 1, the frequency spectrum s(f) has three maxima which correspond, for example, to the materials water, fat and silicone or the resonance frequencies of the protons bound into these materials. For example, the maximum max_{W} is allocated, somewhat above the frequency f=0 Hz, to the material water and the maximum max_{F}, at the frequency −400 Hz, is allocated to the material fat and the maximum max_{Si}, at the frequency −650 Hz, is allocated to the material Si. The identification and allocation of the maxima is not always unambiguously clear, so that confusion of the maxima and thus a false determination of the system frequency can occur.

FIG. 2 shows a graphical representation that illustrates the underlying principle on which the procedure according to the invention is based. On the lower part of the graphical representation, a pulse sequence with an inversion pulse I-RF-PS is shown and an excitation pulse RF-PS which is offset by a time interval TI and is, for example, part of a stimulated echo sequence. In the upper part of the graphical representation, the course over time of the magnetization M_{z} or M_{z}(t) of the materials situated in a region under examination, for example, water and fat are shown. The lower magnetization curve 1 represents the magnetization of the material water and the upper magnetization curve 2 represents the case of the magnetization of the material fat. With the use of the inversion pulse I-RF-PS, the z-component of the magnetic moments of the protons associated with the individual materials is inverted. Therefore, the magnetization M_{z} in the z-direction at the point in time of the inversion is negative. Following the radiation of the inversion pulse I-RF-PS, the magnetic moments of the protons of the individual materials change again in the direction of the starting situation, i.e. the magnetization corresponding to the orientation of the magnetic moments changes slowly to the positive magnetization M_{z} existing before the playing out of the inversion pulse I-RF-PS. However, in the context of this relaxation process, different materials also have different relaxation times. Associated with the different relaxation times, the point in time at which the magnetization of one of the materials assumes the value 0 is also different from material to material.

In FIG. 2, the zero-crossing of the curve 2 of the magnetization M_{z} of the material fat is shown at the point in time TI. If at this point in time TI, an excitation pulse RF-PS is switched, then only the magnetic moments of the protons of the material water are excited into precession, whereas the magnetic moments of the material fat are not excited into precession since the magnetization of the material fat has the value 0 at this moment. This has the consequence that, with the aid of the excitation signal RF-PS, an echo signal is generated only by the material water, whereas the material fat is not excited to emit an echo signal. In this way, therefore, by specifying the time interval TI after which the excitation signal RF-PS is generated, the contribution of a particular material type in the recording of a frequency spectrum is suppressed in a targeted manner. If a number of frequency spectra are subsequently compared with and without suppression of the contribution of pre-determined materials, then based on the lack of the maxima of the respectively suppressed materials, allocation of the maxima of the frequency spectrum to a particular material can be carried out.

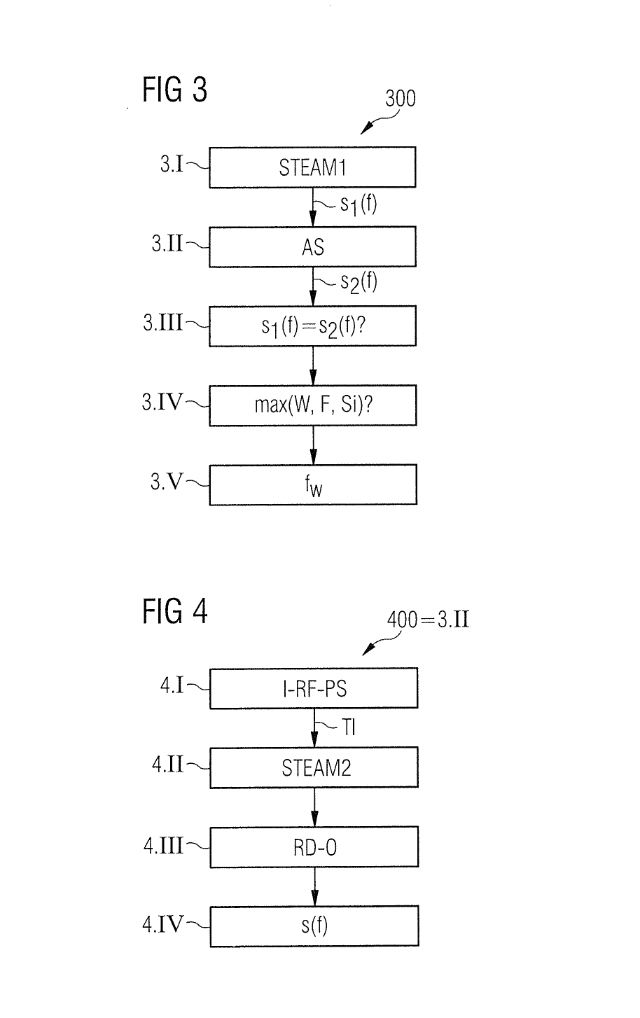

FIG. 3 is a flowchart which a method 300 for determining an MR system frequency in a region under examination according to a first exemplary embodiment of the invention is illustrated.

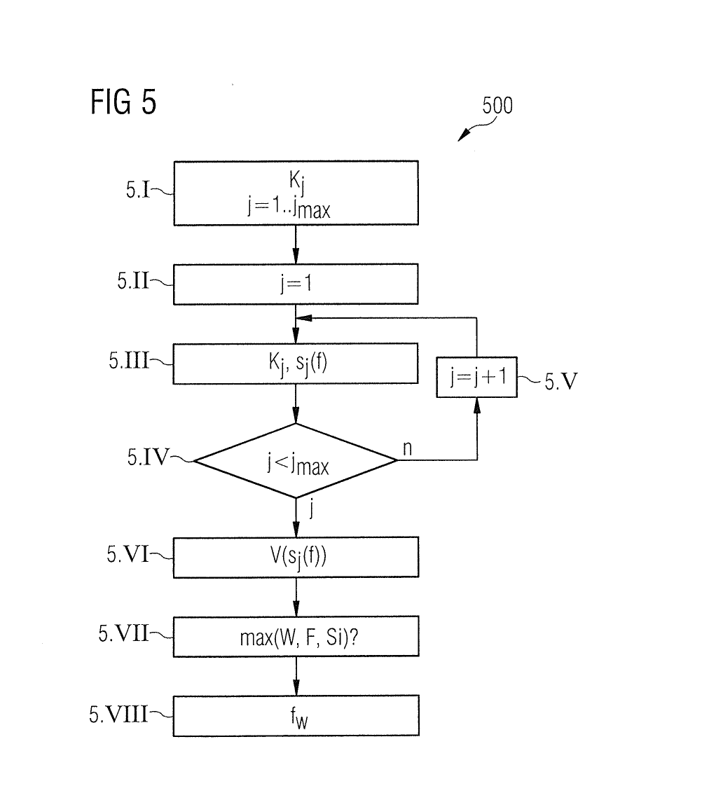

In step 3.I, initially a first stimulated echo sequence STEAM1 is played out, i.e. the magnetic resonance system is controlled with a corresponding echo sequence STEAM. The echo signals excited by the echo sequence STEAM1 are acquired and converted into raw data. With the use of a Fourier transform, from the raw data, a frequency spectrum s₁(f) is generated which comprises all the maxima corresponding to the individual materials present in the region under examination. In step 3.II, a control sequence AS is generated with which a second frequency spectrum s₂(f) for the region under examination is acquired. Herein, however, an echo signal from one of the materials present in the region under examination is suppressed with the method described in relation to FIG. 2. The precise details of the procedure according to the invention on recording of the second frequency spectrum in step 3.II are described in detail in relation to FIG. 4.

In step 3.III, a comparison between the first frequency spectrum s₁(f) and the second frequency spectrum s₂(f) is carried out. For example, it is investigated whether in the second frequency spectrum s₂(f), one of the maxima of the first frequency spectrum is lacking.

Then in step 3.IV, on the basis of the comparison made in step 3.III, the maxima max_{W}, max_{F}, max_{Si} of the first frequency spectrum s₁(f) are allocated to the different materials water W, fat F and silicone Si. As mentioned above, for example, if in the comparison in step 3.II it has been established that a maximum is lacking in the second frequency spectrum s₂(f) and given a knowledge of the echo signal suppressed during generation of the second frequency spectrum s₂(f) of a selected material, an allocation of the lacking maximum in the second frequency spectrum to the selected material is carried out.

Finally, in step 3.V, the system frequency f_{w} is taken as the basis of the allocation of the maxima max_{W}, max_{F}, max_{Si} carried out in step 3.IV. For example, the system frequency is determined with the aid of a cross-correlation between a model function and the experimentally acquired first frequency spectrum s₁(f) or a frequency spectrum s_{1f}(f) filtered therefrom. In order to correlate the model function with the spectrum correctly, however, the allocation of the maxima to the corresponding materials must be known. This information is made available in step 3.IV so that a correct determination of the system frequency f_{w} is ensured.

In FIG. 4 the procedure at step 3.II of the method 300 is illustrated in detail in the flowchart 400. In step 4.I, initially an RF inversion pulse I-RF-PS is generated with a certain pulse width. In order to localize the inversion pulse, a selection gradient with which the effect of the RF inversion pulse to the region under examination is played out synchronously. Subsequently, in step 4.II, after the time TI which is associated with the zero-crossing of the magnetization curve of a particular material, for example silicone, a second stimulated echo sequence STEAM2 with a plurality of RF excitation pulses RF-PS is played out with which now all the materials with the exception of the selected material are excited to emit an echo signal. The RF excitation pulses are accompanied temporally synchronously by gradient pulses which restrict them to the region under examination.

In step 4.III, a readout procedure RD-O takes place, i.e. the echo signals which are read out at the point in time at which the magnetic moments are in phase again due to the stimulated echoes of the excited materials are read out. Subsequently, in step 4.IV, on the basis of the acquired echo signals or the raw data generated therefrom, the second frequency spectrum is generated.

FIG. 5 shows a method 500 for determining an MR system frequency f_{w} for a region under examination according to a second exemplary embodiment of the invention, also illustrated in a flowchart. The underlying difference of the method 500 according to the second exemplary embodiment as compared with the method 300 according to the first exemplary embodiment lies therein that a number of frequency spectra with different configurations Kⱼ, as far as the use of an inversion pulse I-RF-PS and the length of the time interval TI at which the excitation pulse RF-PS is switched are concerned, are acquired and analyzed to determine the system frequency f_{w}.

In step 5.I, firstly a set of configurations Kⱼ for recording each individual frequency spectrum sⱼ(f) is defined, wherein j can take the values 1 to jₘₐₓ. In this regard, jₘₐₓ represents the value of the maximum number of spectra to be recorded. For example, it is useful, if it is assumed that three different materials are present in a region under examination, to record a total of 4 frequency spectra. In this case, for example, the first frequency spectrum s₁(f) can be recorded, as in the method 300, without the use of an inversion pulse I-RF-PS, whereas in the recording of the second to fourth frequency spectra s₂(f) to s₄(f), the echo signal from a respective other material is suppressed by selection or amendment of the corresponding time interval TI after which the RF excitation pulses are switched.

Following specification of the configurations Kⱼ of the individual spectral recordings, in step 5.II, the recording of the first frequency spectrum is initialized, i.e. the control variable j is set to the value 1. In step 5.III, the recording of the first frequency spectrum s₁(f) is carried out with the configuration K₁. Subsequently, in step 5.IV, it is tested whether all the frequency spectra have been recorded. If this is not the case, as indicated in FIG. 5 with “N”, then in step 5.V, the control variable j is incremented by the value 1 and control returns to step 5.III where the next frequency spectrum, in this case, the second frequency spectrum s₂(f) with the configuration K₂ is recorded. The recording of the second frequency spectrum s₂(f) corresponds to the procedure disclosed in detail in connection with FIG. 4. Subsequently, in step 5.IV, it is tested whether all the frequency spectra have already been recorded. If this is not the case, as indicated in FIG. 5 with “N”, then in step 5.V, the control variable j is incremented by the value 1 and control returns to step 5.III where the next frequency spectrum, in this case the third frequency spectrum s₃(f) with the configuration K₃ is recorded, and so on.

When all frequency spectra corresponding to the configurations Kⱼ defined in step 5.I have been acquired, as indicated in FIG. 5 with “Y”, then control passes to step 5.VI in which, similarly to step 3.III, a comparison V(sⱼ(f)) of the acquired frequency spectra sⱼ(f) is carried out. If a number jₘₐₓ of frequency spectra corresponding to the number jₘₐₓ−1 of the materials present is acquired, it is to be expected that each maximum max_{W}, max_{F}, max_{Si} of the first frequency spectrum s₁(f) is to be clearly identified with the aid of the further frequency spectra s₂(f) to sⱼₘₐₓ(f). Then in step 5.VII, on the basis of the comparison made, an allocation of the maxima max_{W}, max_{F} and max_{Si} of the first frequency spectrum s₁(f) to the respective materials present in the region under examination VOI is carried out. In step 5.VIII, the determination of the system frequency f_{w} is carried out as the basis of the allocation carried out in step 5.VII of the maxima max_{W}, max_{F}, max_{Si} to the individual materials present in the region under examination. As previously described in the context of the first exemplary embodiment, the system frequency can be determined with the aid of a cross-correlation between a model function and the experimentally acquired first frequency spectrum s₁(f) or a filtered frequency spectrum s_{1f}(f) generated therefrom. As mentioned above, in order to correlate the model function with the spectrum correctly, however, the allocation of the maxima max_{W}, max_{F}, max_{Si} to the corresponding materials must be known. This information is made available in step 5.VII so that a correct determination of the system frequency f_{w} is ensured.

FIG. 6 shows an exemplary embodiment of a magnetic resonance system 61 according to the invention which is operable in accordance with the method 300, 500 according to the invention. The core of this magnetic resonance system 61 is the magnetic resonance tomography scanner 62 itself in which a patient P is positioned on a patient positioning table 64 (or patient table 64) in an annular basic field magnet 63 which surrounds the scanning space 65. Situated on, and possibly also under the patient, are local coils S, also known as magnetic resonance coils.

The patient table 64 is displaceable in the longitudinal direction, i.e. along the longitudinal axis of the tomography scanner 62. This direction is identified in the 3-D coordinate system, also shown, as the z-direction. Situated within the basic field magnets in the tomography scanner 62 is a whole body coil (not shown in detail) with which the radio-frequency pulses can be emitted and received. Furthermore, the tomography scanner 62 has in the usual manner gradient coils (not shown in the figure) in order to be able to apply a magnetic field gradient in each of the spatial directions x, y, z.

The tomography scanner 62 is controlled by a control computer 66, which is shown separately herein. A terminal 74 is connected to the control computer 66. This terminal 74 has a screen 77, a keyboard 75 and a pointing device 76 for a graphical user interface, for example, a mouse 76 or the like. The terminal 74 serves inter alia as a user interface via which an operator operates the control computer 66 and thus the tomography scanner 62. Both the control computer 66 and also the terminal 74 can also be integral components of the tomography scanner 62.

The magnetic resonance system 61 can also have all the further typical components or features of such systems, for example, interfaces for connection of a communication network, for example, an image information system or the like. For clarity, not all these components are shown in FIG. 6.

Via the terminal 74, an operator can communicate with the control computer and thus ensure the execution of the desired scans in that, for example, the tomography scanner 62 is controlled by the control computer 66 so that the required radio-frequency pulse sequences are emitted by the radio-frequency coils and the gradient coils are switched in a suitable manner. By operation means of the control computer 66, the raw data RD coming from the tomography scanner 62, and needed for the imaging, are acquired. For this purpose, the control computer 66 has a raw data generating processor 67 in which scan signals coming from the tomography scanner 62 are converted into raw data RD. This is achieved, for example, by means of a digitization of the scan signals. In a signal evaluating processor 68, which can be a module of the control computer 66, raw data RD are reconstructed to form image data BD. The image data BD can be visualized, for example, on the screen 77 of the terminal 74 and/or entered in a memory or transmitted via a network. Furthermore, the control computer 66 has a control sequence generating processor 69 with which a control sequence AS, AS1 is generated, according to a protocol which is received, for example, by the terminal 74.

For example, the control sequence generating processor 69 receives from the terminal 74 protocol data PR that has pre-determined parameter values of a pulse sequence AS, AS1 to be determined. The control sequence generating processor 69 is also configured to execute a control sequence AS, AS1 at the magnetic resonance tomography scanner 62, which according to the invention is a first excitation sequence AS1 for acquiring a first frequency spectrum s₁(f) or the control sequence AS described in relation to FIG. 2 and FIGS. 3 to 5, with an inversion pulse.

In addition, the magnetic resonance system 61 shown in FIG. 6 has a system frequency determining device 80. The system frequency determining device 80 is configured to determine a system frequency f_{w} allocated to a region under examination VOI of a patient P. Depending on the materials present at a particular position and the magnetic field varying slightly locally there, the system frequency can also vary locally. The measurement to determine the system frequency preferably comprises the playing out of a so-called STEAM sequence with three RF pulses with which a stimulated echo is generated, wherein each of the three RF pulses coincides with selection gradients in one of the three spatial axes. The echo is Fourier transformed and the signals of all the coil elements are added together. The Fourier transform and addition can be carried out, for example, with the aid of a spectrum generating processor 68a which receives raw data acquired during the measurement from the raw data generating processor 67 and creates spectral data s₁(f). A first frequency spectrum s₁(f) generated is then, for example, further transmitted to the system frequency determining device 80 according to an exemplary embodiment of the invention. The control sequence generating processor 69 is also configured to generate a second control sequence AS which, in accordance with the method 300, 500 according to the invention, with the aid of a preceding inversion pulse, suppresses individual maxima during the recording of additional frequency spectra s₂(f) . . . sⱼₘₐₓ(f). Following the playing out of the second control sequence AS and the acquisition of the corresponding raw data, the aforementioned additional frequency spectra s₂(f) . . . sⱼₘₐₓ(f) are generated by the spectrum generating processor 68a.

The system frequency determining device 80 has an input interface 81 that is configured to receive the spectral data sⱼ(f) from the spectrum generating processor 68a and to pass the spectral data sⱼ(f) to a comparator 82. The comparator 82 determines, based on the acquired frequency spectra sⱼ(f), what differences exist between the individual frequency spectra and, in particular, whether a maximum occurring in the first frequency spectrum s₁(f) no longer occurs in one of the other frequency spectra s₂(f) . . . sⱼₘₐₓ(f). The comparison result VE is passed on to an allocation processor 83 that, based on the comparison result VE, undertakes an allocation ZO of the maxima of the first frequency spectrum s₁(f) to different materials. The allocation ZO is passed on to a system frequency determining processor 84 which determines a system frequency f_{w} on the basis of the allocation ZO.

The system frequency determined f_{w} is subsequently passed via an output interface 85 to the terminal 74. In the terminal 74, the system frequency f_{w} is taken into account in the generation of a protocol PR which, after completion, is passed on to the control computer 66. As previously described, the control computer 66 has a control sequence generating processor 69 that receives from the terminal 74 the protocol data PR, which have pre-determined parameter values of a pulse sequence AS 1 to be determined. With the use of the control sequence generating processor 69, the control sequence AS 1 generated is then provided to the magnetic resonance tomography scanner 62 and the actual image recording can be carried out with the control sequence AS 1 adapted to the system frequency f_{w} that has been determined.

The components of the system frequency determining device 80 required for implementing the invention in a magnetic resonance system 61, for example the comparator 82, the allocation processor 83 and the system frequency determining processor 84 can be provided at least partially or entirely in the form of software components. For example, the system frequency determining device 80 can also be part of the control computer 66 and can include the control sequence generating processor 69. Typical magnetic resonance systems already have programmable control computers in any case, so that in this way, the invention can preferably be realized with the aid of suitable control software, i.e. a suitable computer program is loaded directly into the memory of a programmable control computer 66 of the magnetic resonance system 61 in question, which computer program has program code means in order to carry out the method 300 according to the invention. In this way, already existing magnetic resonance systems are also retrofittable easily and economically.

Some of the components are also realized as subroutines in components already present in the control computer 66 or that existing components are also used for the purpose according to the invention. This relates, for example, to the system frequency determining processor 80, which can be implemented, for example, in a possibly existing system frequency determining device in an existing control computer 66.

Finally, it should again be noted that the methods and devices described above are merely preferred embodiments of the invention and that the invention can also be varied by those skilled in the art without departing from the scope of the invention. Thus, the method and the system frequency determining device have been described primarily on the basis of a magnetic resonance system for recording medical image data. However, the invention is not restricted to use in the medical domain, rather the invention can in principle also be used with magnetic resonance systems for the recording of images for other purposes, for example, for materials testing or the like. For completeness, it should also be mentioned that the use of the indefinite article “a” or “an” does not preclude the relevant feature from also being present plurally. Similarly, the expression “unit” or “module” do not preclude formation by a number of components, which may be spatially distributed.

We claim as our invention:

1. A method for determining a magnetic resonance (MR) system frequency for operating an MR scanner to obtain raw data from a region to be examined of a subject, said region comprising a plurality of different materials, said method comprising:
operating said MR scanner while the subject is situated therein to acquire a first frequency spectrum from said region by executing a first radio-frequency (RF) excitation sequence;
operating said MR scanner to acquire a second frequency spectrum from said region, by executing a second RF excitation sequence at a point in time at which a relaxation curve of magnetization of one of said materials has zero-crossing, and reading out magnetic resonance signals acquired at an echo point in time of said second RF excitation sequence, and determining said second frequency spectrum from the acquired magnetic resonance signals;
providing the first and second frequency spectrums to a computer and, in said computer, comparing said first frequency spectrum with said second frequency spectrum, and thereby obtaining a comparison result;
in said computer, allocating maxima of said first frequency spectrum to respective different materials, among said plurality of materials, based on said comparison result; and
in said computer, determining said system frequency dependent on the allocation of the maxima, and emitting an electronic signal representing said system frequency from said computer.

2. A method as claimed in claim 1 comprising operating said MR scanner to acquire said first frequency spectrum by executing a first stimulated echo sequence as said first RF excitation sequence, and operating said MR scanner to acquire said second frequency spectrum by executing a second stimulated echo sequence as said second RF excitation sequence.

3. A method as claimed in claim 1 comprising operating said MR scanner to acquire a third frequency spectrum from said region by executing a third RF excitation sequence at a point in time at which a relaxation curve of a magnetization of a different one of said materials has a zero-crossing, and comparing the first frequency spectrum, the second frequency spectrum and the third frequency spectrum respectively with each other.

4. A method as claimed in claim 3 comprising operating said MR scanner to acquire said first frequency spectrum by executing a first stimulated echo sequence as said first RF excitation sequence, and operating said MR scanner to acquire said second frequency spectrum by executing a second stimulated echo sequence as said second RF excitation sequence, and operating said MR scanner to acquire said third frequency spectrum by executing a third stimulated echo sequence as said third RF excitation sequence.

5. A method as claimed in claim 3 comprising allocating a maximum of said first frequency spectrum to a respective material, among said plurality of materials, dependent on which frequency spectrum, among said second frequency spectrum and said third frequency spectrum, in which said maximum is suppressed.

6. A method as claimed in claim 3 comprising allocating a maximum of said first frequency spectrum to a respective material, among said plurality of materials, dependent on which point in time the respective second RF excitation sequence or third RF excitation sequence was executed.

7. A method as claimed in claim 1 comprising, in said computer, determining whether a selected material, among said plurality of materials, is present in said region by selecting the point in time of execution of said second RF excitation sequence, during acquisition of said second frequency spectrum, to cause the relaxation curve of the magnetization of the selected material to have a zero-crossing at the selected point in time, and checking in said computer whether the acquired frequency spectrum differs from said first frequency spectrum.

8. A method as claimed in claim 7 comprising, when said second frequency spectrum does not differ from said first frequency spectrum, determining in said computer that the selected material is not present in said region, and when said second frequency spectrum differs from said first frequency spectrum, determining in said computer that said selected material is present in said region.

9. A method as claimed in claim 7 comprising selecting said selected point in time as a point in time at which a zero-crossing of the relaxation curve of the magnetization of a designated material occurs, and selecting said designated material from the group consisting of water, fat and silicone.

10. A method as claimed in claim 1 comprising, in said computer, also determining said system frequency by adapting a model function to one of said first or second frequency spectra.

11. A method as claimed in claim 10 comprising determining said system frequency by adapting said model function to said first frequency spectrum.\

12. A method as claimed in claim 10 comprising adapting the model function to said one of said first or second frequency spectra using a cross-correlation between said first frequency spectrum and said model function and between said second frequency spectrum and said model function.

13. A system frequency determining device for determining a magnetic resonance (MR) system frequency for operating an MR scanner to obtain raw data from a region to be examined of a subject, said region comprising a plurality of different materials, said method comprising:
a computer having an interface configured to receive a first frequency spectrum from said region, acquired with said MR scanner while the subject is situated therein, by executing a first radio-frequency (RF) excitation sequence;
said interface of said computer being configured to receive a second frequency spectrum from said region, acquired with said MR scanner, by executing a second RF excitation sequence at a point in time at which a relaxation curve of magnetization of one of said materials has zero-crossing, and reading out magnetic resonance signals acquired at an echo point in time of said second RF excitation sequence, and said computer being configured to determine said second frequency spectrum from the acquired magnetic resonance signals;
said computer being configured to compare said first frequency spectrum with said second frequency spectrum, thereby to obtain a comparison result;
said computer being configured to allocate maxima of said first frequency spectrum to respective different materials, among said plurality of materials, based on said comparison result; and
said computer being configured to determine said system frequency dependent on the allocation of the maxima, and to emit an electronic signal representing said system frequency from said computer.

14. A magnetic resonance (MR) apparatus comprising:
an MR scanner;
a computer configured to determine an MR system frequency for operating said MR scanner to acquire raw data from a region to be examined of a subject, said region comprising a plurality of materials;
said computer being configured to operate said MR scanner while the subject is situated therein to acquire a first frequency spectrum from said region by executing a first radio-frequency (RF) excitation sequence;
said computer being configured to operate said MR scanner to acquire a second frequency spectrum from said region, by executing a second RF excitation sequence at a point in time at which a relaxation curve of magnetization of one of said materials has zero-crossing, and reading out magnetic resonance signals acquired at an echo point in time of said second RF excitation sequence, and to determine said second frequency spectrum from the acquired magnetic resonance signals;
said computer being configured to compare said first frequency spectrum with said second frequency spectrum, and thereby obtaining a comparison result;
said computer being configured to allocate maxima of said first frequency spectrum to respective different materials, among said plurality of materials, based on said comparison result; and
said computer being configured to determine said system frequency dependent on the allocation of the maxima, and emit an electronic signal representing said system frequency from said computer.

15. A non-transitory, computer-readable data storage medium encoded with programming instructions, said storage medium being loaded into a control computer of a magnetic resonance (MR) apparatus that comprises an MR scanner, said programming instructions causing said computer to determine a system frequency for operating said MR scanner to acquire raw data from a region to be examined of a subject, said region comprising a plurality of materials, by causing said computer to:
operate said MR scanner while the subject is situated therein to acquire a first frequency spectrum from said region by executing a first radio-frequency (RF) excitation sequence;
operate said MR scanner to acquire a second frequency spectrum from said region, by executing a second RF excitation sequence at a point in time at which a relaxation curve of magnetization of one of said materials has zero-crossing, and reading out magnetic resonance signals acquired at an echo point in time of said second RF excitation sequence, and determine said second frequency spectrum from the acquired magnetic resonance signals;
compare said first frequency spectrum with said second frequency spectrum, and thereby obtaining a comparison result;
allocate maxima of said first frequency spectrum to respective different materials, among said plurality of materials, based on said comparison result; and
determine said system frequency dependent on the allocation of the maxima, and emit an electronic signal representing said system frequency from said computer.
